(19) United States
(12) Patent Application Publication
(10) Pub. No.: US 2024/0291241 A1
(43) Pub. Date: Aug. 29, 2024

(54) SEMICONDUCTOR LASER DEVICE

(71) Applicants: THE UNIVERSITY OF TOKYO, Tokyo (JP); AIO CORE CO., LTD., Tokyo (JP)

(72) Inventors: Yasuhiko Arakawa, Tokyo (JP); Masahiro Kakuda, Tokyo (JP); Jinkwan Kwoen, Tokyo (JP); Takahiro Nakamura, Tokyo (JP)

(21) Appl. No.: 18/585,845

(22) Filed: Feb. 23, 2024

(30) Foreign Application Priority Data
Feb. 24, 2023 (JP) 2023-027187
Aug. 21, 2023 (JP) 2023-133791

(51) Int. Cl. H01S 5/34; H01S 5/30; H01S 5/343

(52) U.S. Cl. CPC H01S 5/341; H01S 5/3013; H01S 5/3054; H01S 5/3086; H01S 5/343

(57) ABSTRACT

A semiconductor laser device with a quantum-dot structure allowing for improvement of its high-temperature operation characteristics is provided. The semiconductor laser device has an active-layer structure including one or more active layers. Each active layer has a quantum-dot structure. The quantum-dot structure includes: an island-shaped crystal; a lateral potential barrier layer that at least partially embeds the perimeter of the island-shaped crystal; and an upper crystal layer that covers both an upper end part of the island-shaped crystal and the lateral potential barrier layer. A first bandgap of the lateral potential barrier layer is larger than a second bandgap of the upper crystal layer.

### TECHNICAL FIELD

The present disclosure relates to a semiconductor laser device with a quantum-dot structure and to its related technologies.

### BACKGROUND ART

In recent years, light sources with quantum-dot structures have attracted attention as light sources applicable to optical devices such as optical communication devices, optical integrated circuits, illumination elements, and high-efficiency displays. By using such a quantum-dot structure in the active layer of a semiconductor laser, characteristics such as high-temperature operation characteristics and modulation characteristics are expected to be improved. Conventional technologies related to such semiconductor lasers with the quantum-dot structures are disclosed, for example, in Patent Literatures 1 and 2 (PTLs 1 and 2) below, and also in Non-Patent Literatures 1 and 2 (NPLs 1 and 2) below.

### PATENT LITERATURES

PTL 1: Japanese Patent Application Publication No. 2022-166543.
PTL 2: Japanese Patent Application Publication No. 2022-078795.

### NON PATENT LITERATURES

NPL1: L. Jarvis, B. Maglio, C. P. Allford, S. Gillgrass, A. Enderson, S. Shutts, H. Deng, M. Tang, H. Liu, and P. M. Smowton, “1.3-μm InAs Quantum Dot Lasers with P-type modulation and direct N-type co-doping”, in 28th International Semiconductor Laser Conference (ISLC) (2022), paper WA-02.
NPL 2: Zun-Ren Lv, S. Wang, H. Wang, H.-M. Wang, H.-Y. Chai, X.-G. Yang, L. Meng, C. Ji, and T. Yang, “Significantly improved performances of 1.3 μm InAs/GaAs QD laser by spatially separated dual-doping”, Appl. Phys. Lett. 121 (2), 021105 (2022).

### SUMMARY OF INVENTION

In a case where the conduction band of a quantum-dot structure is split into a plurality of states (sub-bands), the conduction band includes not only a lowest energy state or ground state that can contribute to laser oscillation, but also excited states. Unless the energy difference between the lowest energy state and the excited state is sufficiently larger than a thermal energy (=k_{B}T where k_{B} is Boltzmann's constant) at ambient temperature T, the probability that electrons are present in the excited state becomes high with temperature increasing, and accordingly, the threshold current that is necessary for laser oscillation increases, which has been a problem.

In view of the foregoing, it is a purpose of the present disclosure is to provide a semiconductor laser device with a quantum-dot structure allowing for improvement of high-temperature operation characteristics related to a threshold current.

According to an aspect of the present disclosure, there is provided a semiconductor laser device with an active-layer structure including one or more active layers. Each of the active layers includes one or more quantum-dot structures. Each of the quantum-dot structures includes: an island-shaped crystal; a lateral potential barrier layer having a first bandgap and at least partially embedding the perimeter of the island-shaped crystal; and an upper crystal layer having a second bandgap and covering both an upper end part of the island-shaped crystal and the lateral potential barrier layer, wherein the first bandgap is larger than the second bandgap.

According to an aspect of the present disclosure, the quantum-dot structure includes a lateral potential barrier layer that at least partially embeds the perimeter of an island-shaped crystal, wherein a first bandgap of the lateral potential barrier layer is larger than a second bandgap of an upper crystal layer. With such a combination of the island-shaped crystal, the lateral potential barrier layer, and the upper crystal layer, it is possible to ensure a desired efficiency of current injection (carrier injection) into an active layer while enhancing quantum confinement effect to increase the energy difference between sub-bands (between the lowest energy state and the excited state) of the conduction band of the island-shaped crystal. Accordingly, the threshold current increase at high temperature is suppressed, and thus a semiconductor laser device with the excellent high-temperature operation characteristics can be provided.

### BRIEF DESCRIPTION OF DRAWINGS

In the attached drawings:

FIGS. 1A and 1B are diagrams schematically illustrating the configuration of an active layer with quantum-dot structures according to an embodiment;

FIG. 2 is a diagram schematically illustrating the band structure of an island-shaped crystal (i.e., a quantum dot);

FIGS. 3A and 3B are diagrams schematically illustrating the configuration of an active layer with quantum-dot structures according to another embodiment;

FIG. 4 is a diagram illustrating a schematic configuration of a quantum-dot structure as a modification to the quantum-dot structure illustrated in FIGS. 3A and 3B;

FIG. 5A is a diagram illustrating a STEM image of a section of an actually produced quantum-dot structure, and FIG. 5B is a diagram for description of the STEM image illustrated in FIG. 5A;

FIG. 6 is a graph indicating a composition analysis result of the quantum-dot structure illustrated in FIG. 5A;

FIG. 7 is a diagram illustrating a schematic configuration of a quantum-dot structure as another modification to the quantum-dot structure illustrated in FIGS. 3A and 3B;

FIG. 8 is a graph illustrating calculation results of energy state difference depending on various thicknesses of a lateral potential barrier layer;

FIG. 9 is a graph illustrating calculation results of energy state difference depending on the thickness of the lateral potential barrier layer for two kinds of quantum-dot structures;

FIG. 10A is a graph illustrating calculation results of energy state difference ΔE depending on the thickness of the lateral potential barrier layer of a quantum-dot structure, and FIG. 10B is a diagram illustrating various dimensions of the quantum-dot structure used to obtain the calculation results illustrated in FIG. 10A;

FIG. 11 is a schematic cross-sectional view of the configuration of a semiconductor laser device including an active-layer structure;

FIG. 12 is a schematic cross-sectional view of the configuration of the semiconductor laser device including the active-layer structure;

FIG. 13 is a schematic cross-sectional view of the active-layer structure of the semiconductor laser device illustrated in FIGS. 11 and 12;

FIG. 14 is a cross-sectional view schematically illustrating another example of the active-layer structure of the semiconductor laser device;

FIG. 15 is a schematic cross-sectional view of the configuration of a semiconductor laser device including a diffraction grating structure;

FIG. 16 is a graph illustrating calculation results of high-temperature operation characteristics (temperature dependency of threshold current density) of a semiconductor laser device;

FIG. 17A is a schematic cross-sectional view of an example of the configuration of a semiconductor laser device according to the present embodiment, and FIG. 17B is a schematic cross-sectional view of the active-layer structure of the semiconductor laser device illustrated in FIG. 17A; and

FIG. 18A is a graph illustrating results of PL spectrum measurement of semiconductor laser devices in Examples 1 and 2 at room temperature, and FIG. 18B is a schematic diagram for description of the structure of the semiconductor laser device of Example 1.

### DETAILED DESCRIPTION

Various kinds of embodiments and modifications thereof will be described below in detail with reference to the accompanying drawings. Constituent components denoted by the same reference sign in the drawings have basically the same configuration and the same function.

A semiconductor laser device according to the present embodiment has an active-layer structure including one or more of active layers, and each of the active layers includes one or more quantum-dot structures. A quantum-dot (QD) structure is a quantum confinement structure that is capable of three-dimensionally confining carriers such as electrons in the extremely small dimensions on the nanometer scale. Each quantum-dot structure according to the present embodiment includes: an island-shaped crystal (i.e., a quantum dot) formed on an underlying crystal layer; a lateral potential barrier layer (LPBL) at least partially embedding a perimeter of the island-shaped crystal; and an upper crystal layer covering both an upper end part of the island-shaped crystal and the lateral potential barrier layer. The bandgap of the island-shaped crystal is smaller (in other words, narrower) than the bandgap (first bandgap) of the lateral potential barrier layer and is smaller (in other words, narrower) than the bandgap (second bandgap) of the upper crystal layer. One characteristic is that the bandgap of the lateral potential barrier layer is larger (in other words, wider) than the bandgap of the upper crystal layer. With this characteristic, the energy difference between states (sub-bands) in the conduction band of the island-shaped crystal (i.e., a quantum dot) can be sufficiently increased as compared to thermal energy (=k_{B}T where k_{B} is Boltzmann's constant) at ambient temperature T, and accordingly, the probability that electrons are present in excited states becomes low. Thus, its temperature stability of threshold current that is necessary for laser oscillation can improve.

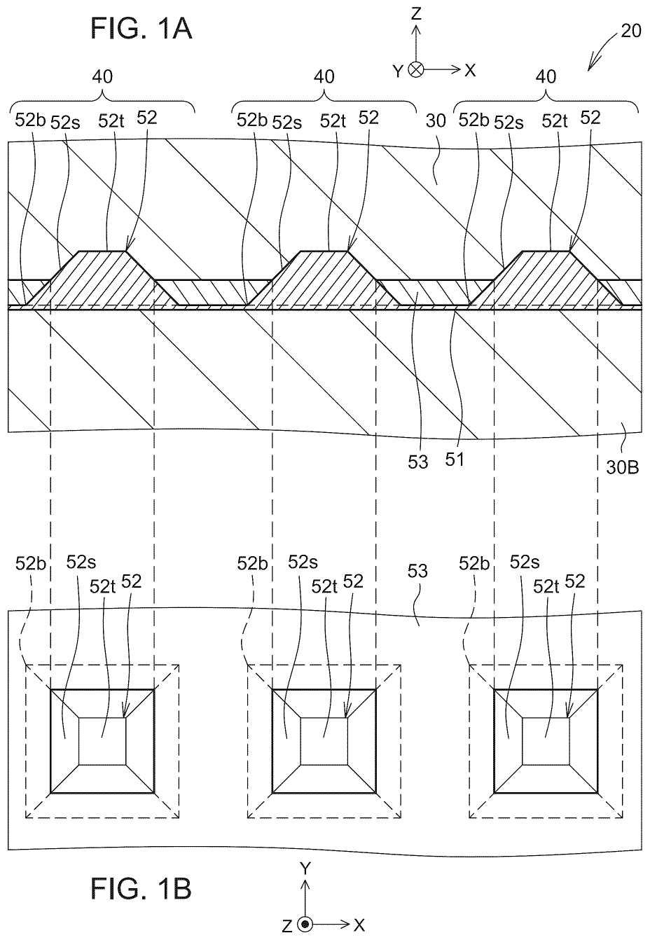

FIGS. 1A and 1B are diagrams schematically illustrating the configuration of an active layer 20 including three quantum-dot structures 40 according to an embodiment. FIG. 1A is a diagram schematically illustrating a sectional structure of the active layer 20 at an X-Z plane, and FIG. 1B is a plan view illustrating part of the active layer 20 (part other than an upper crystal layer 30 of FIG. 1A) when viewed in the positive Z-axis direction, i.e., a height direction. An orthogonal coordinate system is formed by the X-axis, Y-axis, and Z-axis. The drawing plane of FIG. 1B is parallel to an X-Y plane. In the example of FIGS. 1A and 1B, the number of quantum-dot structures 40 is three, but the present invention is not limited thereto.

As illustrated in FIGS. 1A and 1B, each quantum-dot structure 40 includes: a wetting layer 51 formed on the entire surface of an underlying crystal layer 30B; an island-shaped crystal (quantum dot) 52 formed over the underlying crystal layer 30B via the wetting layer 51; a lateral potential barrier layer 53 partially embedding the perimeter of the island-shaped crystal 52 in the lateral direction (in other words, embedding side surfaces 52s of the island-shaped crystal 52) above the underlying crystal layer 30B; and an upper crystal layer 30 covering both an upper end part 52t of the island-shaped crystal 52 and the lateral potential barrier layer 53. The island-shaped crystal 52 has an outer shape of a quadrangular frustum (i.e., a shape obtained by chamfering the apex of a quadrangular pyramid) having one upper end part 52t and four side surfaces 52s. The upper end part 52t of the island-shaped crystal 52 forms a heterojunction with the upper crystal layer 30, and the side surfaces 52s of the island-shaped crystal 52 forms a heterojunction with the lateral potential barrier layer 53 around the entire circumference. In the example of FIGS. 1A and 1B, three island-shaped crystals 52 are arrayed along the X-axis, but the present invention is not limited thereto. The island-shaped crystals 52 as illustrated and non-illustrated island-shaped crystals 52 are distributed along an X-Y plane to form a single quantum dot layer.

The outer shape of the island-shaped crystal 52 of FIGS. 1A and 1B is an example. The outer shape of a quantum dot depends on its crystal growth condition and crystal orientation and thus is not limited to a quadrangular frustum. It is to be noted that, depending on constituent materials of the underlying crystal layer 30B and island-shaped crystal 52, a method of forming the island-shaped crystal 52, and growth process conditions of the island-shaped crystal 52 (for example, a surface orientation of the underlying crystal layer 30B, a temperature condition, and a pressure condition), the outer shape of the island-shaped crystal 52 may be another outer shape such as a polygonal frustum or a cone frustum (i.e., a shape obtained by chamfering the apex of a polygonal pyramid or circular cone) instead of a quadrangular frustum.

The lateral potential barrier layer 53 is formed to embed the perimeter of each island-shaped crystal 52 up to a position lower than the height position of the upper end part 52t of the island-shaped crystal 52. The uppermost end part of the lateral potential barrier layer 53, which forms a junction with the side surfaces 52s of the island-shaped crystal 52, has a substantially rectangular shape when viewed from the top of the example of FIG. 1B. As illustrated in FIG. 1A, the height position of the uppermost end part of the lateral potential barrier layer 53 is controlled to be a height position lower than the height position of the upper end part 52t of the island-shaped crystal 52 and halfway between a lower end part (base end) 52b of the island-shaped crystal 52 and the upper end part 52t.

The bandgap of each island-shaped crystal 52 is smaller than the bandgap of each of the underlying crystal layer 30B, the upper crystal layer 30, and the lateral potential barrier layer 53, which are three-dimensionally surrounds the island-shaped crystal 52. The bandgap of the lateral potential barrier layer 53 is larger (in other words, wider) than the bandgap of the upper crystal layer 30. The underlying crystal layer 30B, the island-shaped crystal 52, the upper crystal layer 30, and the lateral potential barrier layer 53 may be each made of a III-V compound semiconductor material. For example, the island-shaped crystal 52 and the wetting layer 51 may be made of an InAs (indium arsenide)-based monocrystalline material, and the upper crystal layer 30 and the underlying crystal layer 30B may be made of a single crystal material selected from a group consisting of a GaAs (gallium arsenic)-based material, an InP (indium phosphide)-based material, and an InGaAs-based material. The lateral potential barrier layer 53 may be made of a single crystal material selected from a group consisting of an AlGaAs (aluminum gallium arsenide)-based material, an AlAs-based material, an InAlAs-based material, and an InGaAlAs-based material.

For example, any of the following examples 1 to 6 may be employed as a combination of the respective materials of the island-shaped crystal 52, the upper crystal layer 30, and the lateral potential barrier layer 53.

| | |
|---|---|
| Example 1 | Island-shaped crystal/Upper crystal layer/Lateral |
| | potential barrier layer = InAs/GaAs/AlGaAs |
| Example 2 | Island-shaped crystal/Upper crystal layer/Lateral |
| | potential barrier layer = InAs/InP/AlAs |
| Example 3 | Island-shaped crystal/Upper crystal layer/Lateral |
| | potential barrier layer = InAs/InGaAs/InAlAs |
| Example 4 | Island-shaped crystal/Upper crystal layer/Lateral |
| | potential barrier layer = InAs/InGaAs/InGaAlAs |
| Example 5 | Island-shaped crystal/Upper crystal layer/Lateral |
| | potential barrier layer = InAs/InP/InAlAs |
| Example 6 | Island-shaped crystal/Upper crystal layer/Lateral |
| | potential barrier layer = InAs/InP/InGaAlAs |

Each quantum-dot structure 40 may be produced by a crystal growth method such as molecular beam epitaxy (MBE) or metal organic chemical vapor deposition (MOCVD). Each island-shaped crystal 52 may be formed by a fine processing method, a self-assembling growth method, or a method using a combination of the fine processing and the self-assembling growth methods. The self-assembling method may be a method of self-assembling formation based on what is called Volmer-Weber (VW) mode growth or Stranski-Krastanov (SK) mode growth. According to the self-assembling method based on the SK mode growth, through the crystal growth of a compound semiconductor on the underlying crystal layer 30B, a thin wetting layer 51 of approximately several atoms can be formed, and then, a large number of three-dimensional island-shaped crystals 52 can grow on the wetting layer 51. Alternatively, a droplet epitaxy method may be employed in place of the self-assembling method based on the VW mode or SK mode growth. Formation of the wetting layer 51 can be avoided by using the droplet epitaxy method.

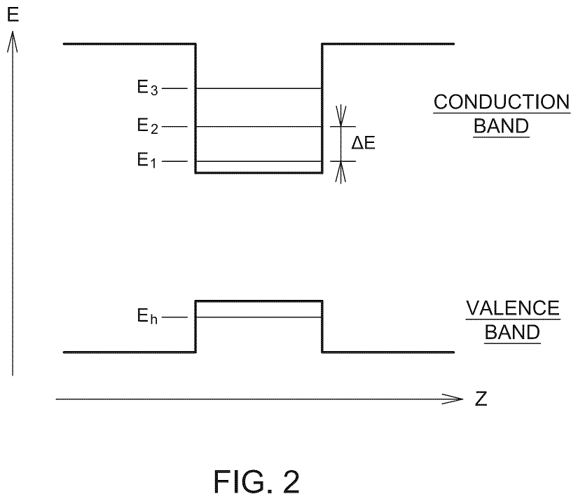

Each quantum-dot structure 40 as described above has a characteristic that the bandgap of the lateral potential barrier layer 53 is larger than the bandgap of the upper crystal layer 30. FIG. 2 is a diagram schematically illustrating a band structure of each island-shaped crystal (quantum dot) 52. In the band structure of FIG. 2, the vertical direction represents energy E and the lateral direction represents height position in the Z-axis direction. The conduction band is split into a plurality of sub-band states E₁, E₂, E₃, and the valence band includes a sub-band state Eₕ. The sub-band state E₁ is the lowest energy state or ground state, and the sub-band states E₂ and E₃ are the first and the second excited states, respectively. Light emission occurs upon coupling of electrons in the lowest energy state E₁ of the conduction band with holes in the sub-band state Eₕ of the valence band in response to when current is injected into the quantum-dot structure 40. In each quantum-dot structure 40 of the present embodiment, the upper end part 52t of the island-shaped crystal 52 forms a junction with the upper crystal layer 30. High quantum confinement effect can be obtained since the bandgap of the lateral potential barrier layer 53 is larger than the bandgap of the upper crystal layer 30. In other words, such high quantum confinement effect can be obtained since energy difference ΔE between the lowest energy state E₁ and the first excited state E₂ in the conduction band of the island-shaped crystal 52 is larger than an energy difference between a lowest energy state and an excited state which are generated in the conduction band of the island-shaped crystal 52 when it is assumed that the side surfaces 52s of the island-shaped crystal 52 do not form a junction with the lateral potential barrier layer 53 but form a junction with the upper crystal layer 30. If the upper crystal layer 30 covering the upper end part 52t of the island-shaped crystal (quantum dot) 52 and the lateral potential barrier layer 53 are both made of a material having a large bandgap, the quantum confinement effect improves and thus the energy difference ΔE can be further increased. However, in this case, the efficiency of current injection into the island-shaped crystal 52 (i.e., efficiency of carrier injection in the vertical direction) potentially deteriorates. In contrast, in the present embodiment, the lateral potential barrier layer 53 is made of a material different from that of the upper crystal layer 30, and the material of the lateral potential barrier layer 53 is selected to have a bandgap larger than the bandgap of the upper crystal layer 30. Therefore, it is possible to ensure a large energy difference ΔE while maintaining the efficiency of current injection. Thus, it is possible to ensure a desired efficiency of current injection while enlarging the energy difference ΔE of the conduction band. Accordingly, the threshold current increase at high temperature is suppressed. With use of such a quantum-dot structure 40, it is possible to provide a semiconductor laser device with the excellent high-temperature operation characteristics.

In each quantum-dot structure 40 illustrated in FIGS. 1A and 1B, the lateral potential barrier layer 53 is formed to partially embed the perimeter of the island-shaped crystal 52. To further improve the quantum confinement effect, the lateral potential barrier layer desirably completely embeds the perimeter of the island-shaped crystal 52 up to the height position of the upper end part 52t of the island-shaped crystal 52.

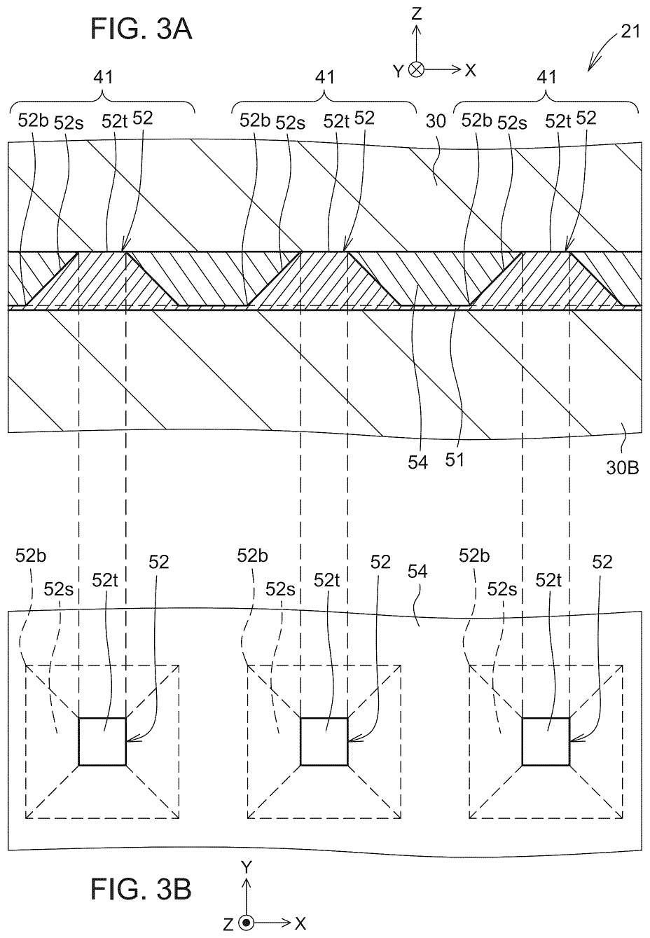

FIGS. 3A and 3B are diagrams schematically illustrating the configuration of an active layer 21 including three quantum-dot structures 41 according to another embodiment. FIG. 3A is a diagram schematically illustrating a sectional structure of the active layer 21 at an X-Z plane, and FIG. 3B is a top view illustrating part of the active layer 21 (part other than the upper crystal layer 30 of FIG. 3A) when viewed in the positive Z-axis direction, i.e., a height direction. The upper surface of FIG. 3B is parallel to an X-Y plane. In the example of FIGS. 3A and 3B, the number of quantum-dot structures 41 is three, but the present invention is not limited thereto.

Each quantum-dot structure 41 illustrated in FIGS. 3A and 3B includes: an island-shaped crystal (quantum dot) 52 formed over the underlying crystal layer 30B via the wetting layer 51; a lateral potential barrier layer 54 completely embedding the perimeter of the island-shaped crystal 52 in the lateral direction (in other words, the side surfaces 52s of the island-shaped crystal 52) above the underlying crystal layer 30B; and the upper crystal layer 30 covering both the upper end part 52t of the island-shaped crystal 52 and the lateral potential barrier layer 54. The upper end part 52t of the island-shaped crystal 52 forms a heterojunction with the upper crystal layer 30, and the side surfaces 52s of the island-shaped crystal 52 form a heterojunction with the lateral potential barrier layer 54 around the entire circumference.

The lateral potential barrier layer 54 is formed to completely embed the perimeter of the island-shaped crystal 52 up to the height position of the upper end part 52t of the island-shaped crystal 52. The height position of the uppermost end part of the lateral potential barrier layer 54, which forms a junction with the side surfaces 52s of the island-shaped crystal 52, is controlled to be the same as the height position of the upper end part 52t of the island-shaped crystal 52. Such a quantum-dot structure 41 can be produced by the same method using the same constituent materials as those of each quantum-dot structure 40 illustrated in FIGS. 1A and 1B.

Each quantum-dot structure 41 as described above has a characteristic that the bandgap of the lateral potential barrier layer 54 is larger than the bandgap of the upper crystal layer 30, and the lateral potential barrier layer 54 completely embeds the side surfaces 52s of the island-shaped crystal 52. Thus, it is possible to obtain higher quantum confinement effect than that of each quantum-dot structure 40 illustrated in FIGS. 1A and 1B. With use of such a quantum-dot structure 41, it is possible to provide a semiconductor laser device with further excellent high-temperature operation characteristics.

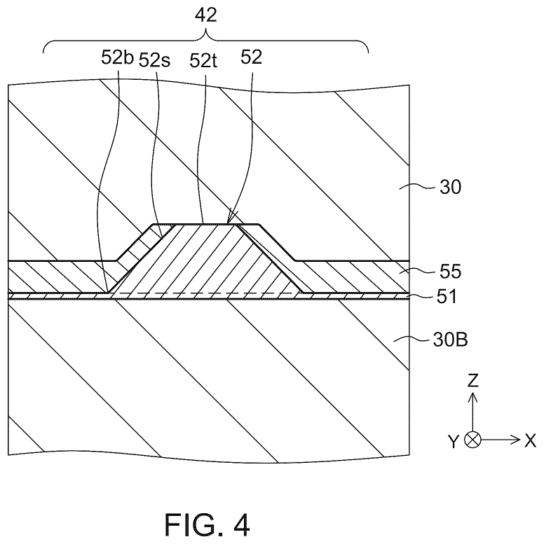

In each quantum-dot structure 41 illustrated in FIGS. 3A and 3B, the upper surface of the lateral potential barrier layer 54 is substantially flat across the entire area of the active layer 21 in the lateral direction, and the height position of the upper surface of the lateral potential barrier layer 54 substantially remains unchanged across the entire area of the active layer 21 in the lateral direction, but the present invention is not limited thereto. FIG. 4 is a diagram illustrating a schematic configuration of a quantum-dot structure 42 as a modification to the quantum-dot structure 41.

The quantum-dot structure 42 illustrated in FIG. 4 includes: an island-shaped crystal (quantum dot) 52 formed over the underlying crystal layer 30B via the wetting layer 51; a lateral potential barrier layer 55 completely embedding the perimeter of the island-shaped crystal 52 in the lateral direction (in other words, embedding the side surfaces 52s of the island-shaped crystal 52) above the underlying crystal layer 30B; and the upper crystal layer 30 covering both the upper end part 52t of the island-shaped crystal 52 and the lateral potential barrier layer 55. The upper end part 52t of the island-shaped crystal 52 forms a heterojunction with the upper crystal layer 30, and the side surfaces 52s of the island-shaped crystal 52 form a heterojunction with the lateral potential barrier layer 55 around the entire circumference. In the vicinity of the island-shaped crystal 52, the upper surface of the lateral potential barrier layer 55 is tilted along the side surfaces 52s and flattened in a region separated in the lateral direction from the upper end part 52t of the island-shaped crystal 52. The quantum-dot structure 42, as well, has a characteristic that the bandgap of the lateral potential barrier layer 55 is larger than the bandgap of the upper crystal layer 30, and the lateral potential barrier layer 55 completely embeds the side surfaces 52s of the island-shaped crystal 52. Thus, as in the case of the quantum-dot structure 41, with use of the quantum-dot structure 42, it is possible to provide a semiconductor laser device with the excellent high-temperature operation characteristics.

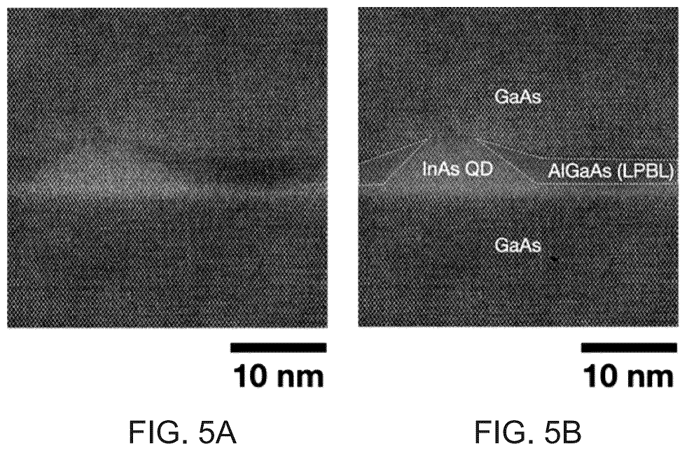

FIG. 5A is a diagram illustrating a STEM image of a section of an actually produced quantum-dot structure. A STEM image is an observation image obtained by scanning transmission electron microscopy (STEM). The STEM image in FIG. 5A is obtained by high-angle annular dark-field STEM (HAADF-STEM). FIG. 5B is a diagram for description of the STEM image of FIG. 5A. As illustrated in FIG. 5B, this quantum-dot structure includes: an InAs quantum dot (InAs QD) formed on an underlying crystal layer made of GaAs; an upper crystal layer made of GaAs; and a lateral potential barrier layer made of AlGaAs (AlGaAs (LPBL)). As in the structure illustrated in FIG. 4, in the vicinity of the InAs quantum dot, the lateral potential barrier layer is formed on the side surfaces of the InAs quantum dot, and the upper surface of the lateral potential barrier layer is tilted along the side surfaces of the InAs quantum dot. It is observed that the upper surface of the lateral potential barrier layer is flattened in a region separated in the lateral direction from an upper end part of the InAs quantum dot. The material (AlGaAs) of the lateral potential barrier layer is not observed at the upper end of the InAs quantum dot.

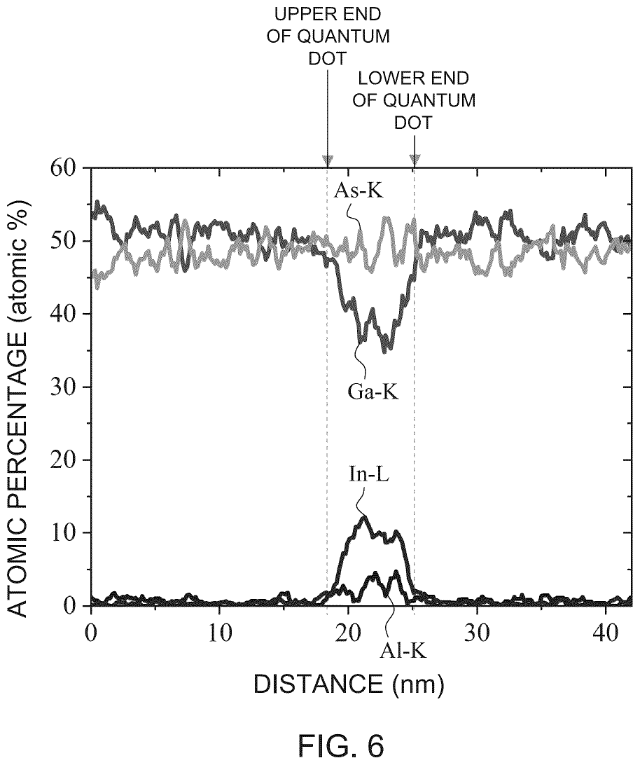

FIG. 6 is a graph indicating a composition analysis result of the quantum-dot structure illustrated in FIG. 5A. The graph was obtained by line scanning analysis using energy dispersive X-ray spectroscopy (EDX). The line scanning was performed in the region of the InAs quantum dot in the thickness direction (vertically downward from above). In the graph of FIG. 6, the horizontal axis represents distance (unit: nm) and the vertical axis represents a constituent element ratio (unit: atomic percentage (atomic %)). The ratios of Al atoms, Ga atoms, As atoms, and In atoms correspond to the intensities of an A|-K line, a Ga—K line, an As—K line, and an In-L line, respectively. According to FIG. 6, it is understood, from the ratios seen in a region from the upper end to the lower end of the InAs quantum dot, that an AlGaAs layer is formed on the side surfaces of the InAs quantum dot.

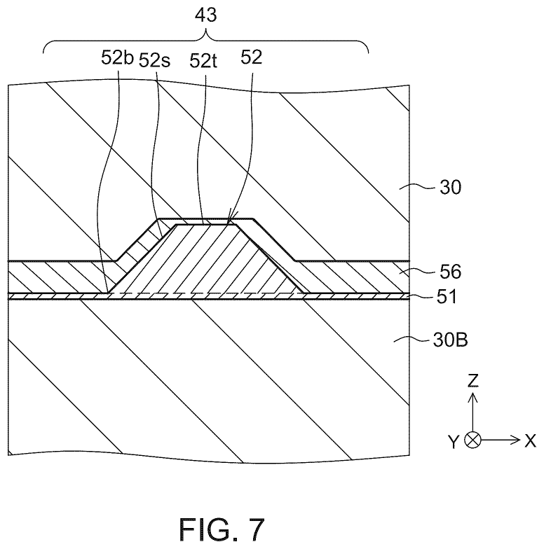

In the quantum-dot structure 42 illustrated in FIG. 4, the upper end part 52t of the island-shaped crystal 52 forms a heterojunction with the upper crystal layer 30. Instead, part of the lateral potential barrier layer may be formed as a thin film on the upper end part 52t of the island-shaped crystal 52 as long as the efficiency of current injection does not substantially deteriorate. In this case, the thin film is interposed between the upper end part 52t and the upper crystal layer 30. FIG. 7 is a diagram illustrating a schematic configuration of a quantum-dot structure 43 as another modification to the quantum-dot structure 41. The quantum-dot structure 43 illustrated in FIG. 7 includes: a lateral potential barrier layer 56 completely embedding the perimeter of an island-shaped crystal 52 in the lateral direction (in other words, the side surfaces 52s of the island-shaped crystal 52). Part of the lateral potential barrier layer 56 is formed as a thin film on the upper end part 52t of the island-shaped crystal 52, and accordingly, the upper end part 52t does not form a junction with the upper crystal layer 30, but the process of forming the lateral potential barrier layer 56 may be controlled so that the thickness of the thin film is within a range where the efficiency of current injection does not substantially deteriorate. Accordingly, with use of the quantum-dot structure 43, as well, it is possible to provide a semiconductor laser device with the excellent high-temperature operation characteristics.

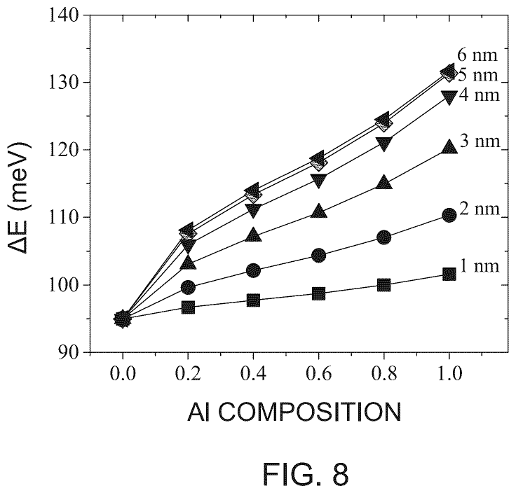

FIG. 8 is a graph illustrating calculation results of the energy state difference ΔE depending on various thicknesses of the lateral potential barrier layer. This calculation was performed based on the quantum-dot structure 40 in FIGS. 1A and 1B. The calculation conditions are as follows:

| | |
|---|---|
| Temperature | 300 K (27° C.) |
| Constituent material of the underlying | GaAs |
| crystal layer and the upper crystal layer | |
| Constituent material of the island-shaped | InAs |
| crystal (quantum dot) | |
| Height of the island-shaped crystal | 6 nm |
| Lateral width of the island-shaped crystal | 20 nm |
| Constituent material of the lateral potential | AlₓGa₁₋ₓAs |
| barrier layer | |
| Thickness of the lateral potential barrier | 1 nm, 2 nm, 3 nm, 4 nm, 5 nm, 6 nm |
| layer | |

In the graph of FIG. 8, the horizontal axis represents Al composition x in the numerical range of 0.0 to 1.0, and the vertical axis represents the energy state difference ΔE (unit: meV) between the lowest energy state and the first excited state in the conduction band of the island-shaped crystal. In a case where the thickness of the lateral potential barrier layer is 6 nm, the height position of the lateral potential barrier layer is the same as the height position of the island-shaped crystal, and accordingly, the quantum-dot structure 41 of FIGS. 3A and 3B is formed. It is known that the bandgap of AlₓGa₁₋ₓAs increases as the value of Al composition x approaches 1.0. According to the graph of FIG. 8, it is understood that as the value of Al composition x increases, the bandgap of the lateral potential barrier layer increases and the energy state difference ΔE increases. It is also understood that the energy state difference ΔE increases from 95 meV to a maximum of 132 meV as the thickness of the lateral potential barrier layer increases.

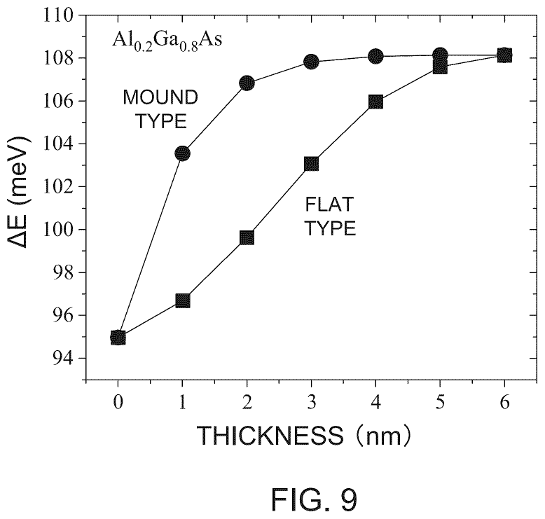

FIG. 9 is a graph illustrating calculation results of the energy state difference ΔE depending on the thickness of the lateral potential barrier layer for two kinds of quantum-dot structures. This calculation was performed based on two kinds of quantum-dot structures, namely the quantum-dot structure 40 (hereinafter also referred to as a “flat type”) of FIGS. 1A and 1B and the quantum-dot structure 42 (hereinafter also referred to as a “mound type”) of FIG. 4. In a case where the thickness of the lateral potential barrier layer is 6 nm, the height position of the lateral potential barrier layer is the same as the height position of the island-shaped crystal, and thus the quantum-dot structure 41 of FIGS. 3A and 3B is formed. The value of Al composition x is constant (=0.2).

In the graph of FIG. 9, the horizontal axis represents the thickness (unit: nm) of the lateral potential barrier layer in the numerical range of 0 to 6 nm, and the vertical axis represents the energy state difference ΔE (unit: meV). According to the graph of FIG. 9, it is understood that, compared to the flat type, the energy state difference ΔE of the mound type more steeply increases at the initial stage in the increasing process of thickness.

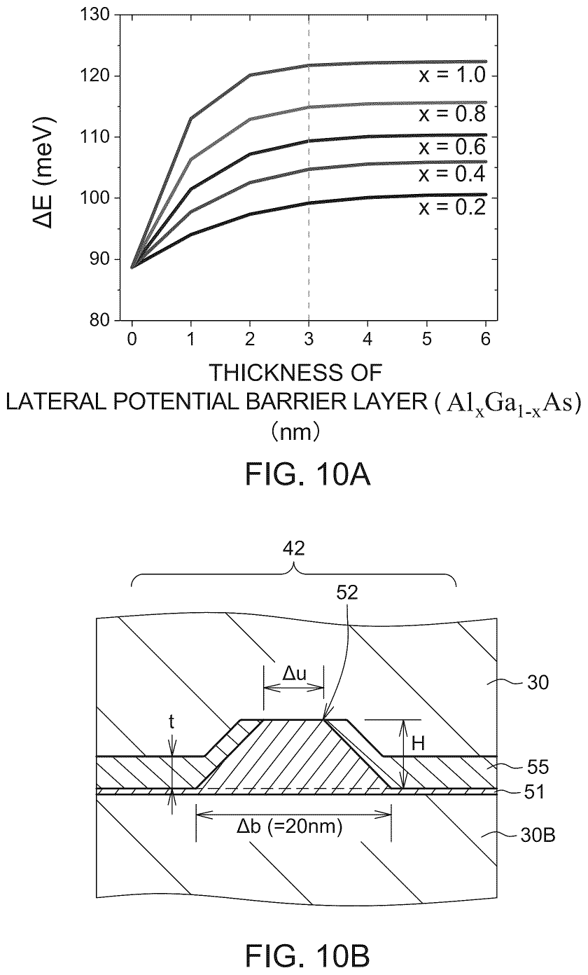

FIG. 10A is a graph illustrating calculation results of the energy state difference ΔE depending on the thickness of the lateral potential barrier layer in the quantum-dot structure of the mound type. FIG. 10B is a diagram illustrating various dimensions of the quantum-dot structure 42 used to obtain the calculation results of FIG. 10A. In the graph of FIG. 10A, the horizontal axis represents Al composition x of an AlₓGa₁₋ₓAs layer as the lateral potential barrier layer 55, and the vertical axis represents the energy state difference ΔE. As illustrated in FIG. 10B, a lower end part of the island-shaped crystal (quantum dot) 52 has a lateral width Δb=20 nm, the island-shaped crystal 52 has a height of H=6 nm, the upper end part of the island-shaped crystal 52 has a lateral width Δu=8 nm, and the lateral potential barrier layer 55 has a thickness t=0 to 6 nm. The shape of the island-shaped crystal 52 is a quadrangular frustum (pyramid shape), the constituent material of the island-shaped crystal 52 is InAs, the constituent material of the upper crystal layer 30 is GaAs, the constituent material of the underlying crystal layer 30B is GaAs, and the temperature is 300K (=27° C.). As illustrated in FIG. 10A, it is understood that, for each value of Al composition x=0.2, 0.4, 0.6, 0.8, and 1.0, the energy state difference ΔE reaches approximately 90% of its maximum value when the thickness t of the lateral potential barrier layer 55 is substantially half of the height of the island-shaped crystal (quantum dot) 52 (t=3 nm).

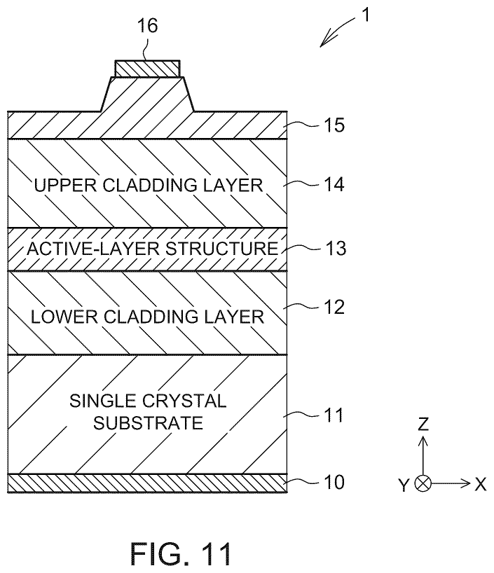

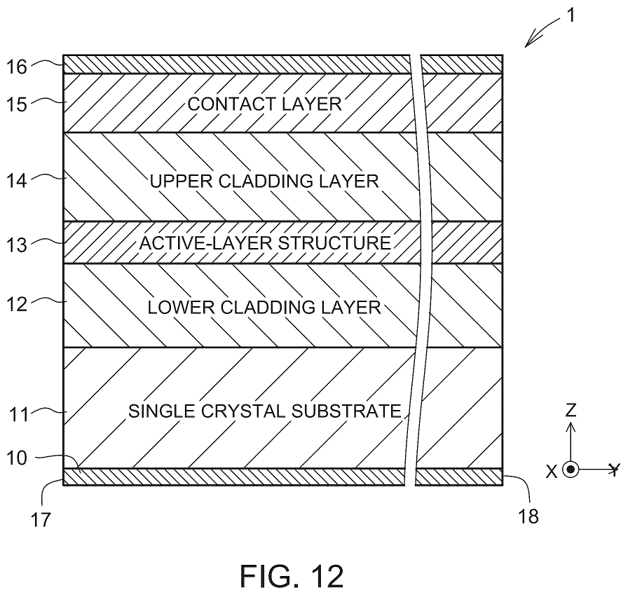

FIGS. 11 to 13 are diagrams schematically illustrating the configuration of a semiconductor laser device 1 including an active-layer structure 13. FIG. 11 is a schematic cross-sectional view of the configuration of the semiconductor laser device 1 when viewed in the positive Y-axis direction, and the cross-section of FIG. 11 is parallel to an X-Z plane. FIG. 12 is a schematic cross-sectional view of the configuration of the semiconductor laser device 1 when viewed in the positive X-axis direction, and the cross-section of FIG. 12 is parallel to a Y-Z plane.

As illustrated in FIGS. 11 and 12, the semiconductor laser device 1 has a configuration in which a single crystal substrate 11, a lower cladding layer 12, the active-layer structure 13, an upper cladding layer 14, and a contact layer 15 are stacked in this order. A lower electrode 10 is provided on the back surface of the single crystal substrate 11. Part of the contact layer 15 is formed in a mesa-striped shape by etching, and an upper electrode 16 is provided on the contact layer 15. For example, the single crystal substrate 11 may be formed as an n-type GaAs substrate, the lower electrode 10 may be formed as an n-type electrode, the lower cladding layer 12 may be formed as an n-type AlGaAs layer, the upper cladding layer 14 may be formed as a p-type AlGaAs layer, the contact layer 15 may be formed as a p-type GaAs layer, and the upper electrode 16 may be formed as a p-type electrode. The semiconductor laser device 1 may have a Fabry-Perot resonator structure. Both end faces 17 and 18 of the semiconductor laser device 1 illustrated in FIG. 12 form resonator end faces for a Fabry-Perot laser.

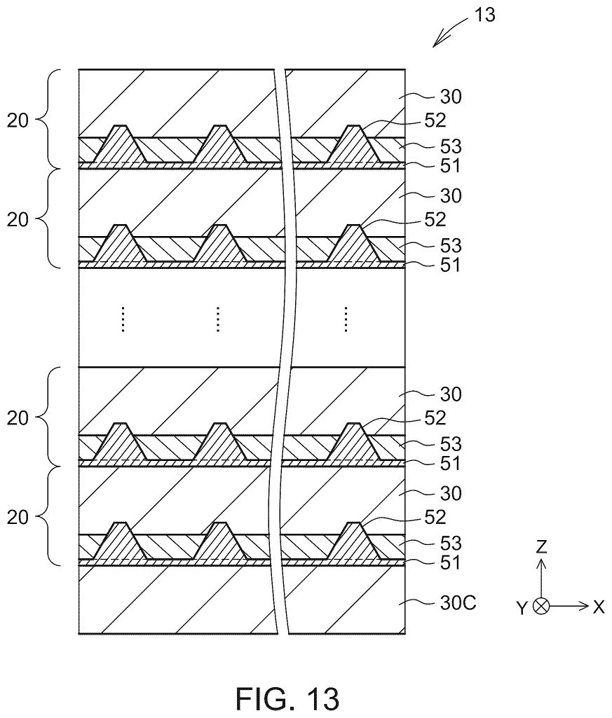

FIG. 13 is a cross-sectional view schematically illustrating an example of the active-layer structure 13 of the semiconductor laser device 1, and the cross-section of FIG. 13 is parallel to an X-Z plane. As illustrated in FIG. 13, the active-layer structure 13 has a structure in which a plurality of active layers 20 are stacked on an underlying crystal layer 30C. The active-layer structure 13 includes the same structures as the quantum-dot structures 40 of the active layer 20 illustrated in FIGS. 1A and 1B, but the present invention is not limited thereto. Each active layer 20 includes a plurality of island-shaped crystals (quantum dots) 52 distributed along an X-Y plane, and the island-shaped crystals 52 form a quantum dot layer.

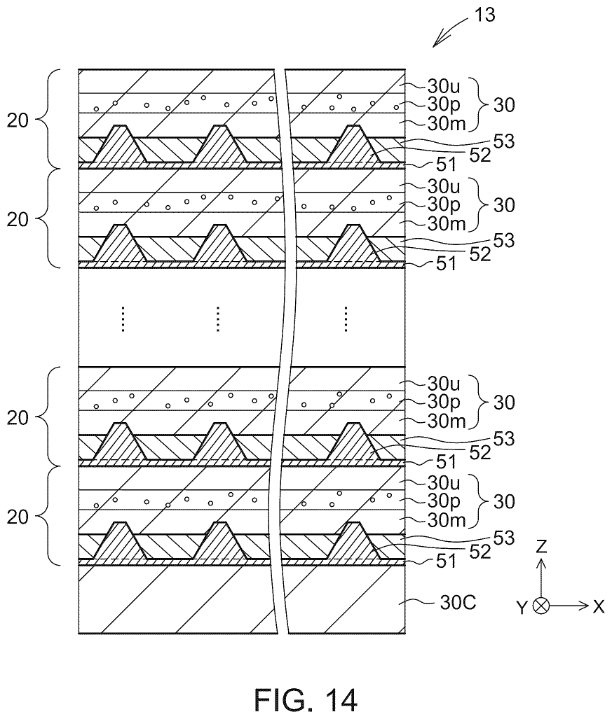

The upper crystal layer 30 may include a layered region in which dopants are introduced. Specifically, the structure of the upper crystal layer 30 may be modified to include a layered region in which any one (first conduction-type dopant) of a p-type dopant and an n-type dopant is introduced by modulation doping. Modulation doping is a process of locally introducing dopants during the growth of the upper crystal layer 30. Modulation doping for introducing a p-type dopant is called p-type modulation doping or modulation p-type doping, and modulation doping for introducing an n-type dopant is called n-type modulation doping or modulation n-type doping. For example, beryllium (Be) is usable as a p-type dopant in a case where the upper crystal layer 30 is made of GaAs. It is known that, by using a layered region in which such p-type dopants are introduced, temperature dependency of threshold current can be suppressed (for example, refer to Non-Patent Literature 1). FIG. 14 is a cross-sectional view schematically illustrating another example of the active-layer structure 13 of the semiconductor laser device 1. The cross-section of FIG. 14 is parallel to an X-Z plane. In the active-layer structure 13 illustrated in FIG. 14, the upper crystal layer 30 of each active layer 20 includes i-type crystal layers 30u and 30m in which no dopants are introduced (that is, undoped), and a p-type layered region 30p as an intermediate layer sandwiched between the crystal layers 30u and 30m. In the example of FIG. 14, the layered region 30p is formed at a position spatially separated from each island-shaped crystal (quantum dot) 52 to avoid substantial influence on the potential of the island-shaped crystal 52.

The configuration of the semiconductor laser device 1 of FIGS. 11 and 12 may be modified to include, in place of the resonator structure for a Fabry-Perot laser, a diffraction grating structure for a distributed feedback (DFB) laser or a diffraction grating structure for a distributed Bragg reflector (DBR) laser. By processing any one layer of the upper cladding layer, active-layer structure and lower cladding layer, the diffraction grating structure for a DFB laser may be formed at a junction interface between the upper cladding layer and the active-layer structure or a junction interface between the lower cladding layer and the active-layer structure. Alternatively, the diffraction grating structure for a DFB laser may be formed at a junction interface between a light guide layer and the active-layer structure by fabricating the light guide layer, the light guide layer being provided between the upper cladding layer and the active-layer structure or between the lower cladding layer and the active-layer structure.

The diffraction grating structure for a DBR laser may be formed by processing one of the upper cladding layer and the lower cladding layer in a waveguide region (in other words, an inactive region in which light generated in the active-layer structure propagates) which is spatially separated from the active-layer structure and optically connected to the active-layer structure. Alternatively, the diffraction grating structure for a DBR laser may be formed by processing a light guide layer formed on the upper cladding layer or the lower cladding layer in the waveguide region (inactive region). A semiconductor laser device including the diffraction grating structure for a DFB laser or the diffraction grating structure for a DBR laser can operate as a light source that outputs a laser beam in a single longitudinal mode.

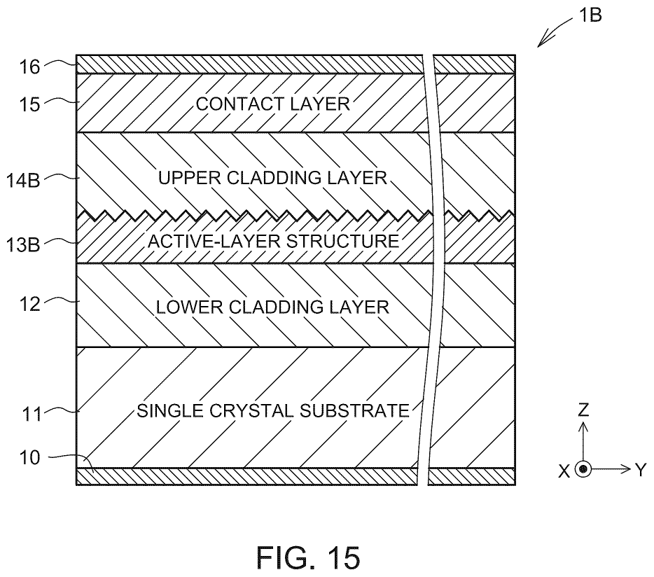

FIG. 15 is a schematic sectional view of the configuration of a semiconductor laser device 1B including an exemplary diffraction grating structure. The semiconductor laser device 1B has a configuration in which the single crystal substrate 11, the lower cladding layer 12, an active-layer structure 13B, an upper cladding layer 14B, and the contact layer 15 are stacked in this order. The lower electrode 10 is provided on the back surface of the single crystal substrate 11, and the upper electrode 16 is provided on the contact layer 15. The basic configuration of the semiconductor laser device 1B is the same as the basic configuration of the semiconductor laser device 1 illustrated in FIGS. 11 and 12 except that the diffraction grating structure for a DFB laser is formed at a junction interface between the active-layer structure 13B and the upper cladding layer 14B.

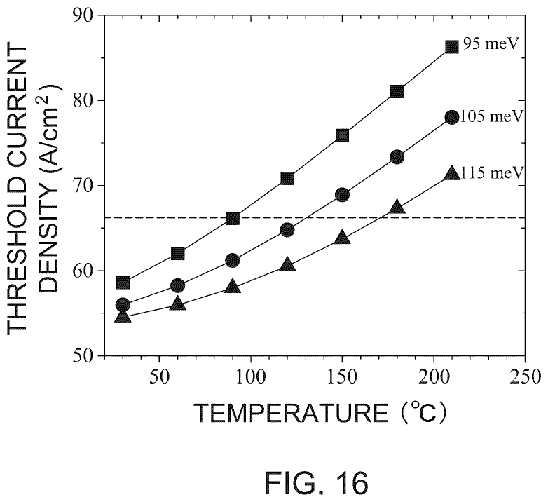

FIG. 16 is a graph illustrating calculation results of high-temperature operation characteristics (temperature dependency of threshold current density) of a semiconductor laser device. In the graph of FIG. 16, the horizontal axis represents temperature (unit: ° C.), and the vertical axis represents the threshold current density (unit: A/cm²). This calculation was performed based on the structure of the semiconductor laser device 1 illustrated in FIGS. 11, 12, and 14. The calculation conditions are as follows:

| | |
|---|---|
| Constituent material of the underlying | GaAs |
| crystal layer and the upper crystal layer | |
| Constituent material of the island-shaped | InAs |
| crystal (quantum dot) | |
| Constituent material of the lateral potential | AlGaAs |
| barrier layer | |
| Temperature | 30 to 210° C. |
| Quantum dot density (in-plane density) | 5 × 10¹⁰ cm⁻² |
| The number of quantum dot layers | 10 |
| Interval of quantum dot layers | 40 nm |
| Lowest energy state transition energy | 0.954 eV (corresponding to a |
| | wavelength of 1300 nm) |
| P-type modulation doping density of a | 1 × 10¹⁷ cm⁻³ |
| dopant (Be) in the layered region | |
| Threshold gain | 16 cm⁻¹ (equivalent to a mirror loss of |
| | a resonator length 750 μm) |
| Ratio of the conduction band and the | 8:1 |
| valence band at transition energy | |
| difference | |
| State degeneracy (including spin degree of | 2, 4, 8, 12 in order from the lowest |
| freedom) | energy state |
| Transition energy difference ΔE between | 95 to 115 meV |
| adjacent states | |

The threshold current density at the energy state difference ΔE=95 me V and 90° C. was assumed as the upper limit for laser oscillation. The upper limit is illustrated with a dotted line in the graph of FIG. 16. According to the graph of FIG. 16, it is understood that laser oscillation is possible up to 120° C. (=90° C.+30° C.) for ΔE=105 meV, and laser oscillation is possible at 150° C. (=90° C.+60° C.) for ΔE=115 meV. Thus, it has been proved that laser oscillation is possible up to higher temperature.

A semiconductor laser device of another embodiment will be described below.

In the process of forming island-shaped crystals (quantum dots), a method called direct doping, which introduces dopants into the island-shaped crystal, has been conventionally employed to improve the gain of a quantum dot laser. Direct doping for introducing an n-type dopant is called direct n-type doping, and direct doping for introducing a p-type dopant is called direct p-type doping. It is considered that direct doping can improve carrier recombination efficiency by adjusting the band structure of each quantum dot to enhance the effect of confining carriers such as electrons and holes, thereby lowering threshold current necessary for laser oscillation. However, there is a problem with a quantum dot laser provided with direct doping that temperature dependency of the threshold current may be relatively high. On the other hand, modulation doping as described above can suppress temperature dependency of the threshold current, whereas there is a problem that the threshold current may increase due to internal loss. Non-Patent Literatures 1 and 2 disclose using a combination of direct n-type doping and modulation p-type doping to solve those problems. The combination of direct doping and modulation doping is called co-doping or dual-doping.

According to Non-Patent Literatures 1 and 2, with co-doping comprised of direct n-type doping and modulation p-type doping, the above-described problems related to direct n-type doping can be solved to some extent in the temperature range of 27° C. to 97° C. (refer to FIGS. 3 and 4 of Non-Patent Literature 1 and FIG. 5(a) of Non-Patent Literature 2, for example). However, temperature dependency of the threshold current in a high temperature range of 100° C. or higher is not suppressed only by applying modulation p-type doping to a quantum dot laser provided with direct n-type doping. It is considered that direct n-type doping enhances the effect of confining electrons in the conduction band of each quantum dot to increase the probability of radiative recombination. As described above, unless the energy state difference ΔE in the conduction band of a quantum dot is sufficiently larger than thermal energy at ambient temperature T, there arises a problem that threshold current increases because the probability that electrons are present in the lowest energy state becomes low while the probability that electrons are present in excited states becomes high in a high temperature range. Even if the effect of confining electrons is enhanced by direct n-type doping, the threshold current potentially increases in a high temperature range as the probability that the confined electrons are present in excited states becomes high.

The inventors of the present application have found that it is possible to suppress temperature dependency of the threshold current in a high temperature range by applying the above-described lateral potential barrier layer (LPBL) to a quantum dot laser provided with direct doping.

Each quantum-dot structure of a semiconductor laser device according to the present embodiment includes an island-shaped crystal (quantum dot) formed on an underlying crystal layer, wherein any one (second conduction-type dopant) of an n-type dopant and a p-type dopant is introduced in the island-shaped crystal by direct doping. With such direct doping, the band structure of each quantum dot is controlled to enhance the effect of confining carriers so that it can be expected that carrier recombination efficiency improves and the threshold current decreases. Each quantum-dot structure further includes: a lateral potential barrier layer that is at least partially embedding the perimeter of the island-shaped crystal in which the dopant is introduced; and an upper crystal layer covering both an upper end part of the island-shaped crystal and the lateral potential barrier layer. The bandgap of the island-shaped crystal is smaller (in other words, narrower) than the bandgap (first bandgap) of the lateral potential barrier layer and smaller (in other words, narrower) than the bandgap (second bandgap) of the upper crystal layer. The bandgap of the lateral potential barrier layer is larger (in other words, wider) than the bandgap of the upper crystal layer. Accordingly, the energy difference ΔE between sub-band states (between the lowest energy state and the excited state) in the conduction band of the island-shaped crystal (quantum dot) can be larger than thermal energy (=k_{B}T where k_{B} is Boltzmann's constant) at ambient temperature T, and thus, the probability that electrons are present in the lowest energy state becomes high while the probability that electrons are present in the excited state becomes low. Accordingly, it is possible to decrease the threshold current by direct doping and improve temperature stability of the threshold current in a high temperature range as well.

In a direct doping process, in order to avoid degradation of optical properties of the semiconductor laser device, it is preferable that a dopant is not introduced in the process of forming a wetting layer but is selectively introduced only in the process of forming each island-shaped crystal. The dopant concentration is desirably controlled so that one to two dopant atoms are introduced in each quantum dot (in other words, so that the number of dopant atoms per quantum dot is approximately in the range of 1.0 to 2.0).

To further suppress temperature dependency of the threshold current, the above-described upper crystal layer preferably includes a layered region in which the dopant (first conduction-type dopant) is introduced by modulation doping. The layered region may be formed at a position spatially separated from the island-shaped crystal not to provide substantive influence on the potential of the island-shaped crystal (quantum dot).

In an embodiment, any one of a p-type dopant and an n-type dopant may be introduced into the lateral potential barrier layer (LPBL) by modulation doping.

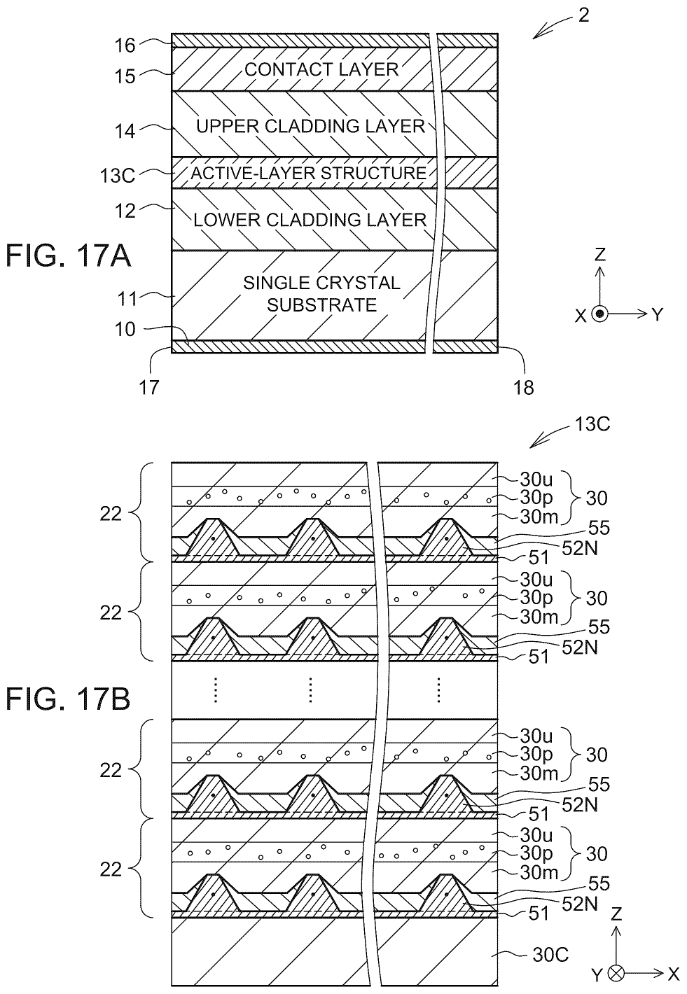

FIG. 17A is a schematic cross-sectional view of an example of the configuration of a semiconductor laser device 2 according to the present embodiment, and FIG. 17B is a cross-sectional view schematically illustrating an example of an active-layer structure 13C of the semiconductor laser device 2 illustrated in FIG. 17A. FIG. 17A is a cross-sectional view when viewed in the positive X-axis direction, and the cross-section of FIG. 17A is parallel to a Y-Z plane. The semiconductor laser device 2 has a configuration in which the single crystal substrate 11, the lower cladding layer 12, the active-layer structure 13C, the upper cladding layer 14, and the contact layer 15 are stacked in this order. Both end faces 17 and 18 of the semiconductor laser device 2 form resonator end faces for a Fabry-Perot laser.

The configuration of the semiconductor laser device 2 is the same as the configuration of the semiconductor laser device 1 of FIG. 12 except that the active-layer structure 13C is included in place of the active-layer structure 13 of FIG. 12. The configuration of the semiconductor laser device 2 of FIG. 17A may be modified to have, in place of the resonator structure for a Fabry-Perot laser, a diffraction grating structure for a distributed feedback laser or a diffraction grating structure for a distributed Bragg reflective laser.

As illustrated FIG. 17B, the active-layer structure 13C has a structure in which a plurality of active layers 22 are stacked on the underlying crystal layer 30C. The quantum-dot structure of each active layer 22 includes: the wetting layer 51 formed on the entire surface of an underlying crystal layer (the underlying crystal layer 30C or the upper crystal layer 30); an island-shaped crystal (quantum dot) 52N formed over the underlying crystal layer via the wetting layer 51; the lateral potential barrier layer 55 embedding the perimeter of the island-shaped crystal 52N in the lateral direction; and the upper crystal layer 30 covering both an upper end part of the island-shaped crystal 52N and the lateral potential barrier layer 55. The upper end part of the island-shaped crystal 52N forms a heterojunction with the upper crystal layer 30, and the side surfaces of the island-shaped crystal 52N form a heterojunction with the lateral potential barrier layer 55 around the entire circumference. The bandgap of the lateral potential barrier layer 55 is larger than the bandgap of the upper crystal layer 30 and larger than the bandgap of the island-shaped crystal 52N. The quantum-dot structure may be basically formed of the same constituent material by the same fabrication method as that used for each above-described quantum-dot structure 40.

An n-type dopant is introduced in each island-shaped crystal 52N by direct n-type doping. The n-type dopant concentration is desirably controlled so that one to two dopant atoms are introduced in each island-shaped crystal (each quantum dot) 52N (in other words, so that the number of dopant atoms per quantum dot is approximately in the range of 1.0 to 2.0). For example, silicon (Si) is usable as the n-type dopant in a case where each island-shaped crystal 52N is made of InAs. To avoid degradation of optical properties of the semiconductor laser device 2, it is preferable that the n-type dopant is not introduced in the process of forming the wetting layer 51 but is selectively introduced only in the process of forming each island-shaped crystal 52N.

The upper crystal layer 30 includes the crystal layers 30u and 30m and the p-type layered region 30p, wherein the layered region 30p is a region in which a p-type dopant is introduced by modulation p-type doping. In the example of FIG. 17B, the layered region 30p is formed at a position spatially separated from each island-shaped crystal (quantum dot) 52N not to provide substantive influence on the potential of the island-shaped crystal 52N and is configured as an intermediate layer sandwiched between the crystal layers 30u and 30m. The crystal layers 30u and 30m are i-type layers in which no dopant is introduced (that is undoped). The p-type dopant may be locally introduced during the growth of the upper crystal layer 30. Beryllium (Be) is usable as the p-type dopant in a case where the upper crystal layer 30 is made of GaAs.

In the example of FIG. 17B, each quantum-dot structure has a structure of the mound type. Specifically, in the vicinity of each island-shaped crystal 52N, the lateral potential barrier layer 55 is formed on the side surfaces of the island-shaped crystal 52N, and the upper surface of the lateral potential barrier layer 55 is tilted along the side surfaces of the island-shaped crystal 52N. The upper surface of the lateral potential barrier layer 55 is flattened in a region separated in the lateral direction from the upper end part of the island-shaped crystal 52N. Nonetheless, the quantum-dot structure is not limited to the mound type. The configuration of the lateral potential barrier layer 55 may be modified to have the structure illustrated in FIGS. 1A to 1B, FIGS. 3A to 3B, or FIG. 7 instead of the mound type. The outer shape of the island-shaped crystal 52N may be, for example, a quadrangular frustum when viewed from top (when viewed in the positive Z-axis direction), but the present invention is not limited thereto.

In each quantum-dot structure of the semiconductor laser device 2 described above, the lateral potential barrier layer 55 is formed to embed the perimeter of the island-shaped crystal (quantum dot) 52N in which an n-type dopant is directly introduced. In addition, the upper crystal layer 30 is formed to cover the upper end part of the island-shaped crystal 52N and the lateral potential barrier layer 55. The bandgap of the lateral potential barrier layer 55 is selected such that the material of the lateral potential barrier layer 55 has a bandgap larger than the bandgap of the upper crystal layer 30, and thus it is possible to obtain a large quantum confinement effect while maintaining the efficiency of current injection into the island-shaped crystal 52N (i.e., the efficiency of carrier injection in the vertical direction). Since the bandgap of the lateral potential barrier layer 55 is larger than the bandgap of the island-shaped crystal 52N, the energy difference ΔE between sub-band states (between the lowest energy state and the excited state) in the conduction band of the island-shaped crystal 52N can be increased. Accordingly, it is possible to decrease the threshold current by direct n-type doping and improve temperature stability of the threshold current in a high temperature range. Moreover, the upper crystal layer 30 includes the layered region 30p in which a p-type dopant is introduced by modulation p-type doping. Accordingly, temperature dependency of the threshold current can be further suppressed.

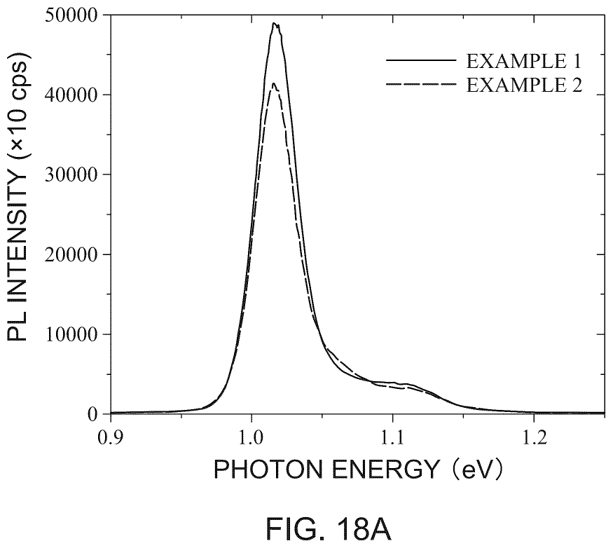

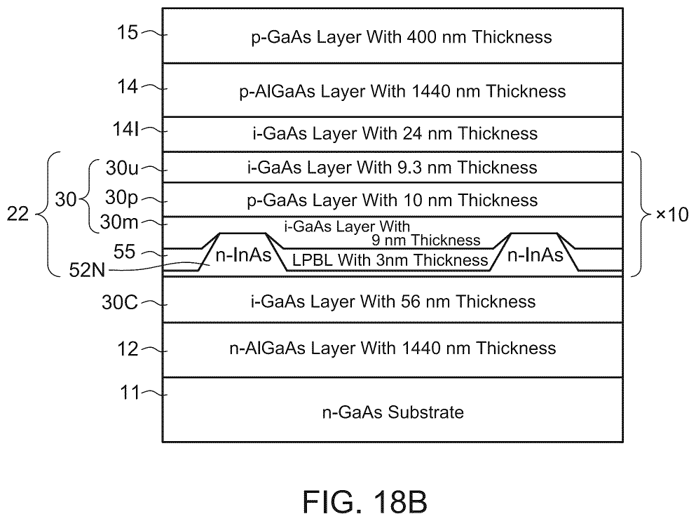

FIG. 18A is a graph illustrating results of photoluminescence (PL) spectrum measurement of two kinds of actually produced semiconductor laser devices at room temperature. In the graph of FIG. 18A, the horizontal axis represents photon energy (unit: eV) corresponding to wavelength, and the vertical axis represents PL intensity (unit: ×10 cps). The unit “cps” means counts per second. One of the two kinds of semiconductor laser devices is Example 1 that basically has the same structure as the semiconductor laser device 2 illustrated in FIGS. 17A and 17B. Example 1 is provided with direct n-type doping and modulation p-type doping (co-doping). The other kind is Example 2 that has the same structure as Example 1 except that direct n-type doping is not provided. Example 2 is provided with modulation p-type doping.

FIG. 18B is a schematic diagram for description of the structure of the semiconductor laser device of Example 1. As illustrated in FIG. 18B, the structure of Example 1 includes: the single crystal substrate 11 made of an n-type GaAs substrate; the lower cladding layer 12 made of an n-type AlGaAs layer; the underlying crystal layer 30C made of an i-type GaAs layer; a structure in which ten active layers 22 are stacked; an i-type GaAs layer 14I; the upper cladding layer 14 made of a p-type AlGaAs layer; and the contact layer 15 made of a p-type GaAs layer. Each active layer 22 includes: a large number of island-shaped crystals (quantum dots) 52N each made of n-type InAs; the lateral potential barrier layer (LPBL) 55 made of Al_{0.2}Ga_{0.8}As layer and embedding the perimeter of the island-shaped crystals 52N; and the upper crystal layer 30 made of a GaAs layer and covering both the upper end part of each island-shaped crystal 52N and the lateral potential barrier layer 55. The upper crystal layer 30 includes: the layered region 30p made of a p-type GaAs layer in which a p-type dopant (Be) is introduced by modulation p-type doping; and the crystal layers 30u and 30m made of i-type GaAs layers sandwiching the layered region 30p. An n-type dopant (Si) is introduced in each island-shaped crystal (quantum dot) 52N by direct n-type doping. The n-type dopant concentration is 0.5×10¹¹ cm⁻², which corresponds to one dopant atom per quantum dot. In addition, Be is introduced as a p-type dopant in the layered region 30p. The p-type dopant concentration is 2.0×10¹¹ cm⁻², which corresponds to four dopant atoms per quantum dot.

As illustrated in FIG. 18A, it has been proved that Example 1 provided with co-doping (modulation p-type doping and direct n-type doping) provides a light emission intensity that is approximately 1.2 times higher than Example 2 not provided with direct n-type doping.

Various kinds of embodiments and modifications thereof described above are merely exemplary and do not limit the range of the present invention. It should be understood that change, addition, and modifications to the above-described embodiments may be performed as appropriate without departing from the scope and range of the present invention. The range of the present invention should be interpreted based on the description of the claims, and it should be understood that the present invention includes equivalents thereof.

### INDUSTRIAL APPLICABILITY

Semiconductor laser devices according to the present disclosure are applicable to optical devices such as optical communication devices and/or optical integrated circuits.

What is claimed is:

1. A semiconductor laser device with an active-layer structure that includes one or more active layers, each active layer including one or more quantum-dot structures, wherein each of the one or more quantum-dot structures includes:
an island-shaped crystal;
a lateral potential barrier layer having a first bandgap and at least partially embedding a perimeter of the island-shaped crystal; and
an upper crystal layer having a second bandgap and covering the lateral potential barrier layer and an upper end part of the island-shaped crystal, the first bandgap being larger than the second bandgap.

2. The semiconductor laser device according to claim 1, wherein an energy difference between a lowest energy state and an excited state in the conduction band of the island-shaped crystal is larger than an energy difference between a lowest energy state and an excited state which are generated in the conduction band of the island-shaped crystal when it is assumed that a side surface of the island-shaped crystal does not form a junction with the lateral potential barrier layer but forms a junction with the upper crystal layer.

3. The semiconductor laser device according to claim 1, wherein:
the lateral potential barrier layer embeds the perimeter of the island-shaped crystal up to a position lower than a height position of the upper end part of the island-shaped crystal; and
the upper crystal layer forms a junction with the upper end part of the island-shaped crystal.

4. The semiconductor laser device according to claim 1, wherein the lateral potential barrier layer embeds the perimeter of the island-shaped crystal up to a height position of the upper end part of the island-shaped crystal.

5. The semiconductor laser device according to claim 4, wherein the upper crystal layer forms a junction with the upper end part of the island-shaped crystal.

6. The semiconductor laser device according to claim 1, wherein the upper crystal layer includes a layered region in which a first conduction-type dopant is introduced by modulation doping.

7. The semiconductor laser device according to claim 6, wherein the first conduction-type dopant is a p-type dopant.

8. The semiconductor laser device according to claim 1, wherein a second conduction-type dopant is introduced in the island-shaped crystal by direct doping.

9. The semiconductor laser device according to claim 8, wherein the upper crystal layer includes a layered region in which a first conduction-type dopant is introduced by modulation doping.

10. The semiconductor laser device according to claim 9, wherein the first conduction-type dopant is a p-type dopant and the second conduction-type dopant is an n-type dopant.

11. The semiconductor laser device according to claim 1, wherein the island-shaped crystal, the upper crystal layer, and the lateral potential barrier layer are each made of a III-V compound semiconductor material.

12. The semiconductor laser device according to claim 11, wherein:
the island-shaped crystal is made of an InAs-based material; and
the upper crystal layer is made of one material selected from a group consisting of a GaAs-based material, an InP-based material, and an InGaAs-based material.

13. The semiconductor laser device according to claim 11, wherein the lateral potential barrier layer is made of one material selected from a group consisting of an AlGaAs-based material, an AlAs-based material, an InAlAs-based material, and an InGaAlAs-based material.

14. The semiconductor laser device according to claim 1, wherein the semiconductor laser device includes a resonator structure for a Fabry-Perot laser.

15. The semiconductor laser device according to claim 1, wherein the semiconductor laser device includes a diffraction grating structure for a distributed feedback laser or a diffraction grating structure for a distributed Bragg reflective laser.
